(19) United States
(12) Patent Application Publication
(10) Pub. No.: US 2008/0185717 A1
(43) Pub. Date: Aug. 7, 2008

(54) SEMICONDUCTOR DEVICE INCLUDING BUMP ELECTRODES

(75) Inventor: Dai SASAKI, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 12/027,280

(22) Filed: Feb. 7, 2008

(30) Foreign Application Priority Data
Feb. 7, 2007 (JP) 2007-028231

(51) Int. Cl. H01L 23/48; H01L 21/60

(52) U.S. Cl. 257/737; 438/120; 257/E23.01; 257/E21.519

(57) ABSTRACT

A semiconductor device includes a semiconductor chip mounted on a printed circuit board with a chip electrode being coupled to a board electrode via a bump electrode. An insulating resin layer including therein conductive particles is interposed between the bump electrode and each of the chip electrode and board electrode. The conductive particles couple together the bump electrode and the each of the chip electrode and the board electrode. The conductive particles and the bump electrode are deformed to have a flat shape due the stress applied between the semiconductor chip and the printed circuit board.

This application is based upon and claims the benefit of priority from Japanese patent application No. 2007-028231 the disclosure of which is incorporated herein in its entirety by reference.

### BACKGROUND OF THE INVENTION

1. Field of the Invention

The present invention relates to a semiconductor device and a method of manufacturing the same. More particularly, the present invention relates to a semiconductor device wherein chip electrodes formed on a semiconductor chip and board electrodes formed on a printed circuit board are connected together via bump electrodes, and also to a method of manufacturing the same.

2. Description of the Related Art

In some conventional semiconductor devices, a semiconductor chip is mounted on a printed circuit board by using a wire-bonding technique. In a fabrication process using the wire-bonding technique, the semiconductor chip is fixed, in a face-up posture, onto the printed circuit board, and the electrode pads (chip electrodes) formed on the chip is then connected to the electrode pads (board electrodes) formed on the printed circuit board by using wires. In recent years, a flip-chip bonding technique has come into frequent use, because it is increasingly required that electronic apparatuses be smaller and smaller. In the flip-chip bonding technique, the semiconductor chip is first placed on the printed circuit board, in a face-down posture, and then the electrode pads formed on the chip are connected to the electrode pads formed on the circuit boards by using bump electrodes,

The flip-chip bonding technique is advantageous in two respects in order to improve the operational performance of electronic apparatuses. First, it allows reduction of the occupied area of the semiconductor chip on the surface of the printed circuit board. Second, it reduces the total length of interconnections that connect the semiconductor chip to the printed circuit board.

In any device that includes a semiconductor chip and a printed circuit board coupled together by using the flip-chip bonding technique, a large stress develops in the bump electrodes while the device is operating at a high speed to generate a large amount of heat. This is due to the difference between the semiconductor chip and the circuit board in terms of coefficient of linear thermal expansion. If the stress excessively increases, the stress will break the bump electrodes and adjacent interconnections coupled thereto, inevitably resulting in malfunction of the electronic apparatus. To solve this problem, Patent Publication JP-2002-076201A describes that insulating resin layer fills the gap between the semiconductor chip and the printed circuit board or is applied to the vicinity thereof, before the insulating resin is cured by heat etc.

The above patent publication teaches that the stress developed in the bump electrodes at a high temperature is absorbed in the insulating resin layer, and the stress in the bump electrodes is thereby reduced. However, a large stress may remain in some of the bump electrodes, due to the difference between the semiconductor chip and the printed circuit board in terms of the coefficient of linear thermal expansion. In this case, the large stress in the bump electrodes may break the bump electrodes or the adjacent interconnections. It is therefore desired that a mounting structure which can suppress such a thermal stress be provided for the semiconductor device.

### SUMMARY OF THE INVENTION

In view of the foregoing problem, it is an object of the present invention to provide a semiconductor device including a semiconductor chip including a chip electrode, a printed circuit board including a board electrode, and a bump electrode coupling together the chip electrode and the board electrode, and also to a method of manufacturing is device. More specifically, it is an object of the present invention to provide a semiconductor device wherein no large stress develops in the bump electrode and a method of manufacturing such a semiconductor device.

The present invention provides a semiconductor device including: a semiconductor chip including thereon a first terminal electrode; a printed circuit board including thereon a second terminal electrode; a bump electrode provided between the first electrode and the second terminal electrode for coupling together the first terminal electrode and the second terminal electrode; and an insulating resin layer provided between the bump electrode and at least one of the first and second terminal electrodes, the insulating resin layer including therein conductive particles which are in direct contact with the bump electrode and the at least one of the first and second terminal electrodes.

The present invention also provides a method of manufacturing a semiconductor device including a semiconductor chip including a first terminal electrode, and a printed circuit board including a second terminal electrode, the method consecutively including: forming an insulating resin layer on at least one of the first and second terminal electrodes, the insulating resin layer including therein conductive particles; depressing a bump electrode onto at least one of the first and second terminal electrodes from above the insulating resin layer, thereby allowing the conductive particles to be in contact with the bump electrode and the at least one of the first and second terminal electrodes; and curing the insulating resin layer.

The above and other objects, features and advantages of the present invention will be more apparent from the following description, referring to the accompanying drawings.

### BRIEF DESCRIPTION OF THE DRAWINGS

FIG. 1 is a sectional view showing the configuration of a semiconductor device according to an embodiment of the present invention;

FIG. 2 is an enlarged sectional view of the potion encircled by a rectangle II shown in FIG. 1;

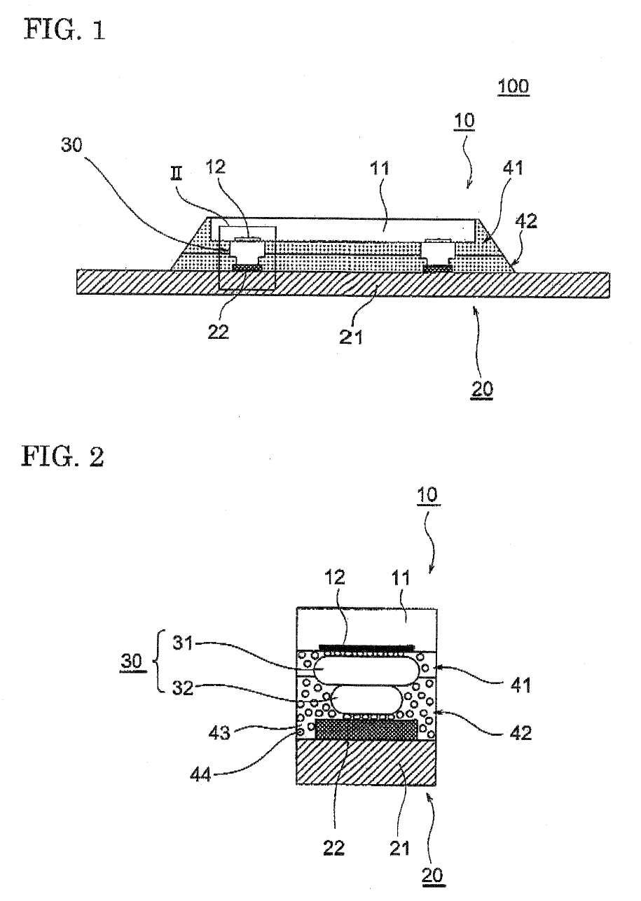

FIGS, 3A to 3H are sectional views showing consecutive steps of a process for fabricating the semiconductor device shown in FIG. 1.

### DETAILED DESCRIPTION OF THE INVENTION

An exemplary embodiment of the present invention will be described in detail with reference to the accompanying drawings. FIG. 1 is a sectional view showing the configuration of a semiconductor device according to the embodiment of the invention. The semiconductor device 100 includes a semiconductor chip 10 and a printed circuit board 20. The semiconductor chip 10 is mounted on the printed circuit board 20 and coupled thereto by using bump electrodes 30, that is, by using the flip-chip bonding technique.

The semiconductor chip 10 includes a main body 11 and a plurality of electrode pads (chip electrodes) 12 formed on the main surface of the main body 1. The printed circuit board 20 includes a main body 21 and a plurality of electrode pads (board electrodes or bonding lands) 22 formed on that surface of the main body 21, on which the semiconductor chip 10 is mounted. In the main body 21 of the circuit board 20, a plurality of interconnection layers are formed and connected to the electrode pads 22.

The bump electrodes 30 used in this embodiment are known as stud bumps. The stud bumps are in the form of projections that protrude from the bottom surface of the semiconductor chip 10 toward the top of the printed circuit board 20. Between the semiconductor chip 10 and the printed circuit board 20, there are provided a first anisotropic conductive film 41 and a second anisotropic conductive film 42. More precisely, the first anisotropic conductive film 41 is provided on the bottom of the semiconductor chip 10, and the second anisotropic conductive film 42 is provided on the printed circuit board 20.

Those anisotropic conductive films 41 and 42 are made of insulating resin layer in the shape of film, including therein a large number of conductive particles 44 which are uniformly dispersed in the insulating resin layer. The insulating resin layers are made of thermosetting resin. In other words, the anisotropic conductive films 42 and 43 are formed by heating the layers of thermosetting resin to cure the resin. It is to be noted that FIG. 1 shows only a few of the electrode pads 12 and 22 and only a few of the bump electrodes 30.

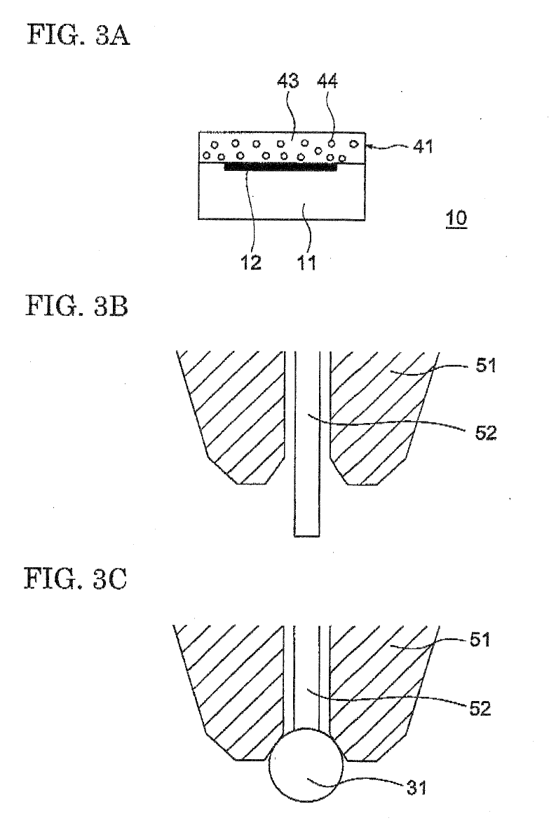

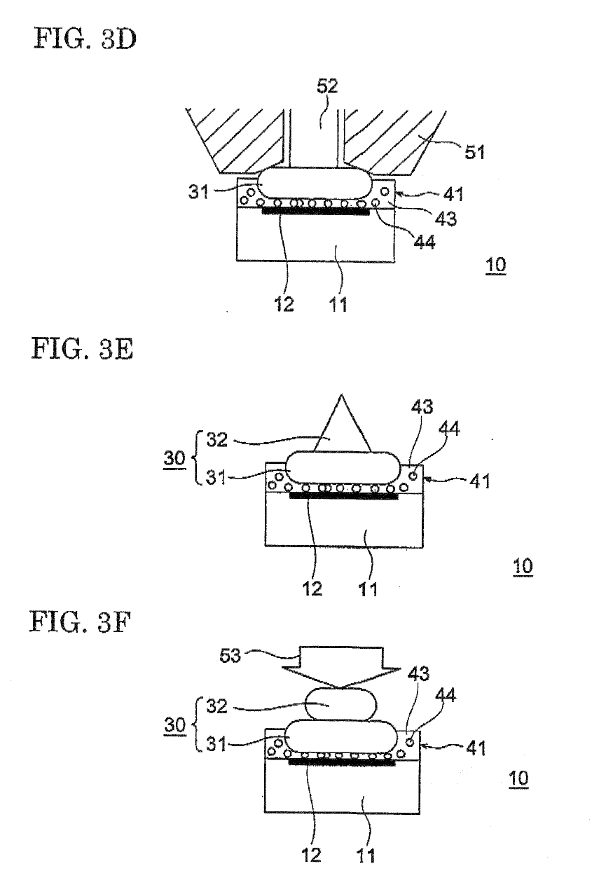

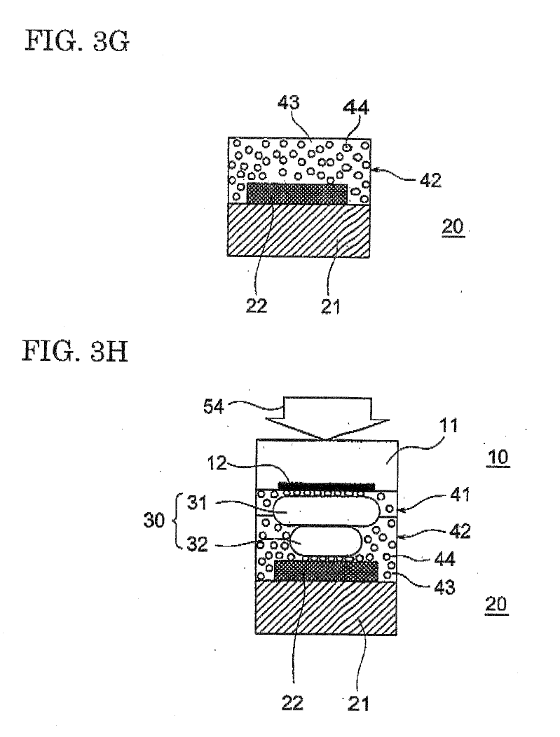

FIG. 2 is an enlarged sectional view of the portion encircled by a rectangle II in FIG. 1, showing the coupling structure between the semiconductor chip 10 and the printed circuit board 20. As understood from FIG. 2, the bump electrodes 30 include a first portion 31 and a second portion 32. The first portion 31 is disposed on the side of the semiconductor chip 10, whereas the second portion 32 is disposed on the side of the printed circuit board 20. The first portion 31 I is larger than the second portion 32, in terms of planer size. The bump electrodes 30 have a substantially flat top surface and a substantially flat bottom surface. The bump electrodes 30 are made of gold (Au) including, for example, about 0.1 wt. % of palladium (Pd).

The conductive particles 44 are elastic and substantially spherical, and have an electrically conductive surface. The conductive particles 44 are spaced apart from one another, or group by group, at least in the in-plane direction of the insulating resin layers 43. Hence, each of the anisotropic conductive films 41 and 42 has an insulating property in the in-plane direction thereof The first portion 31 of each bump electrode 30 has a bottom surface received in the first anisotropic conductive film 41, and a top surface received in the second anisotropic conductive film 42. The second portion 32 of each bump electrode 30 is received, in its entirety in the second anisotropic conductive film 42.

Some of the conductive particles 44 are located at the gap between each electrode pad 12 of the semiconductor chip 10 and the first portion 31 of the bump electrode 30 while contacting both the electrode pad 12 and the first portion 31. Metal compound (not shown) is formed at the interface between the electrode pads 12 and the conductive particles 44, and also between the conductive particles 44 and the first portion 31 of the bump electrodes 30. The metal compound fixes and electrically couples together the electrode pads 12 and the first portion 31 of the bump electrodes 30. The conductive particles 44 sandwiched between the electrode pads 21 and the first portion 31 of the bump electrodes 30 are deformed to assume a somewhat flat shape, and are fixed in position by the cured insulating resin layer 43.

Conductive particles 44 are interposed also between each electrode pad 22 of the printed circuit board 20 and the second portion 32 of each bump electrode 30, while contacting both the electrode pad 22 and the second portion 32. Metal compound (not shown) is formed at the interface between the electrode pads 22 and the conductive particles 44, and also between the conductive particles 44 and the second portion 32 of the bump electrodes 30. The metal compound fixes and electrically couples together the electrode pads 22 and the second portion 32 of the bump electrodes 30. The conductive particles 44 sandwiched between the electrode pads 22 and the second portion 32 of the bump electrodes 30 re deformed to have a somewhat flat shape, and are fixed in position by the cured insulating resin layer 43.

In order to effectively disperse the stress generated between the semiconductor chip 10 and the printed circuit board 20, the first and second anisotropic conductive films 41 and 42 have a substantially equal coefficient of linear thermal expansion. The coefficient of linear thermal expansion is set at an intermediate value between the coefficient of linear thermal expansion f the semiconductor chip 10 and that of the printed circuit board 20.

As described above, in et present embodiment, the conductive particles 44 disposed in the anisotropic conductive films 41 and 42 have elasticity and are interposed between the electrode pads 12 or 22 and the bump electrodes 30. Therefore, the conductive particles 44 are elastically deformed, if a thermal stress occurs in tie bump electrodes 30, to maintain the electric conduction between the electrode pads 12 or 22 and tie bump electrodes 30 In this structure, since the conductive particles 44 are deformed in accordance with the stress generated in the adjacent bump electrode 30, a larger deformation of the conductive particles 44 reduces a larger stress in the bump electrodes 30 This effectively prevents a large stress from remaining locally in some of the bump electrodes 30.

In the present embodiment, the conductive particles 44, which are interposed between tie electrode pads 12 or 22 and tie bump electrodes 30, are deformed to assume a flat shape and fixed in position by tie cured insulating resin layer 43. Hence, when a stress is generated in the bump electrodes 30, tie conductive particles 44 are elongated and flattened to decrease the stress effectively. That is, tie stress in the bump electrodes 30 can be reduced, because the conductive particles 44 are interposed between the electrode pads 21 of the semiconductor chip 10 and the associated bump electrodes 30, and also between the electrode pads 22 of tie printed circuit board and associated bump electrodes 30.

FIGS. 3A to 3H are sectional views depicting consecutive steps of a process manufacturing the semiconductor device shown in FIG. 1. First, as shown in FIG. 3A, the first anisotropic conductive film 41 is bonded onto the circuit surface of the semiconductor chip 10, covering at least tie electrode pads 12. Thereafter, as shown in FIG. 3B, a gold wire 52 is fed through a capillary nozzle 51. The distal end of the gold wire 52 is melted by electric discharge, as shown in FIG. 3C, to form a gold ball, which is later formed as the first portion 31 of one of the bump electrode 30. The size of the gold ball is adjusted by the discharge voltage applied to form the first portion 31 of the bump electrodes.

Subsequently, the nozzle 51 is aligned with one of the electrode pads 12 and then lowered, while being applied with ultrasonic vibration, whereby the ball-shaped first potion 31 is depressed into the first anisotropic conductive film 41. In the anisotropic conductive film 41, the gold ball 31 is deformed to be flat, providing a first portion 31 of the bump electrode 30, as shown in FIG. 3D, with the conductive particles 44 remaining between the bottom of the first portion 31 and the electrode pad 12. Metal compound (not shown) is formed between the electrode pad 12 and the conductive particles 44 and between the particles 44 and the first portion 31, fixing and electrically coupling together the electrode pad 12 and the first portion 31 of the bump electrode 30. At is stage, the conductive particles 44 assume a flat shape due to the depression between the electrode pad 21 and the first portion 31 of the bump electrode 30, and protrude to some degree into the first portion 31.

Subsequently, the nozzle 51 is raised to move the gold wire 52 away from the first portion 31 of the bump electrode 30, and hence leaving a cone-shaped gold electrode, as shown in FIG. 3E. The gold electrode configures the second portion 32 of the bump electrode 30. Thereafter, as shown in FIG. 3F, heat and pressure are applied from above to the second portion 32 of the bump electrode 30, in the direction of the arrow 53. The second portion 32 is thereby flattened. More specifically, a flat member having a planar size larger than that of the semiconductor chip 10 applies a pressure to all the bump electrodes 30 at a time. Thus, all the second portions 32 have a uniform height Further, the insulating resin layer 43 is provisionally cured, while flattening the conductive particles 44 interposed between the first portion 31 of the bump electrodes 30 and the electrode pads 12. The curing is performed at, for example, 150 degrees C., and the pressure applied to each bump electrode 30 is about 100 mN (milli-Newton).

Thereafter, as shown in FIG. 3G, the second anisotropic conductive film 42 is bonded onto that surface of the printed circuit board 20, on which the semiconductor chip 10 is to be mounted, to cover at least the electrode pads 22. Thereafter, as shown in FIG. 3H, the semiconductor chip 10 is placed and depressed onto the printed circuit board 20, with the second portion 32 of the bump electrodes 30 being aligned with the electrode pads 22. Thus, each second portion 32 is depressed into the second anisotropic conductive film 42. Thereafter, ultrasonic vibration is applied, with the electrode pads 22 and the second portion 32 of the bump electrodes contacting the conductive particles 44. Metal compound (not shown) is thereby formed between the electrode pads 22 and the conductive particles 44 and between the conductive particles 44 and the second portion 32. The metal compound thus formed fixes and electrically couples together the electrode pads 22 and the second portion 32.

Subsequently, as shown in FIG. 3H, heat and pressure are applied from the rear side of the semiconductor chip 10 in the direction of an arrow 54 The conductive particles 44 sandwiched between the first portion 31 and the electrode pads 12 and between tie second portion 32 and the electrode pads 22 are thereby deformed to have a flat shape. The insulating resin layer 43 in the first anisotropic conductive film 41 and second anisotropic conductive film 42 is completely cured. This curing is performed at, for example, 200 degrees C., and the pressure applied to each bump electrode 30 is about 1 N. As a result, the semiconductor device 10 shown in FIG. 1 is manufactured.

In the method according to the present embodiment, ultrasonic vibration is applied to the structure, while the conductive particles 44 remain in contact with the electrode pads 12 and 22 or the bump electrodes 30, to form the metal compound. The metal compound fixes and electrically couples together the electrode pads 12 and 22 and the bump electrodes 30, with the particles 44 sandwiched between the electrode pads 12 and the associated pads 30 and between the electrodes 22 and the associated pads 30. In addition, the conductive particles 44 are deformed to assume a flat shape, because the insulating resin layer 43 is cured, with the conductive particles 44 being sandwiched between the electrode pads 12 and 22 and the associated bump electrodes 30.

In the semiconductor device 100, the conductive particles 44 may be interposed between the bump electrodes 30 and the associated electrode pads 12 of the semiconductor chip 10, or between the bump electrodes 30 and the corresponding electrode pads 22 of the printed circuit board 20 Further, the semiconductor chip 10 may be an IC package that includes a bare chip. Further, the bump electrodes 30 need not be stud electrodes so long as they are flat at top and bottom surfaces thereof. Furthermore, the particles 44 need not be electrically conductive in the entirety thereof. Rather, they may be electrically conductive at least in the surface region. The conductive particles 44 can effectively reduce the stress in the bump electrodes 30 because they have appropriate elasticity.

In the method described above, the semiconductor chip 10 may be mounted on the printed circuit board 20 after the bump electrodes 30 have been secured to the circuit board 20. Further, in the step of FIG. 3A and the step of FIG. 3G, the main surface of the semiconductor chip 10 and the chip-mounting surface of the printed circuit board 20 may be coated with insulating paste-like resin including therein conductive particles, instead of bonding of the anisotropic conductive film as described above.

In the semiconductor device of the above embodiment, when a stress develops in the bump electrodes, the conductive particles are deformed to reduce the stress in the bump electrodes. In this structure, the deformation in the conductive particles reduces a stress in the bump electrodes to a degree depending on the intensity of the stress generated on the bump electrodes adjacent to the conductive particles. This effectively prevents a large stress from remaining locally in the bump electrode.

As described heretofore, in an embodiment of the semiconductor device of the present invention, the conductive particles may have elasticity, and can therefore effectively reduce the stress in the bump electrodes. In another embodiment of the invention, a metal compound may be formed between the conductive particles and the bump electrode, and between the conductive particles and at least one of the first and second terminal electrodes. In this case, the metal compound can enhance the coupling reliability between the bump electrodes and the first and second terminal electrodes.

As described above, the present invention may have the following embodiments.

The conductive particles between the bump electrodes and at least one of the first and second terminal electrodes may be deformed to assume a flat shape due to the depression thereof. In this structure, when a stress develops in the bump electrodes, the conductive particles are elongated, thereby effectively decreasing the stress in the bump electrodes. In this case, the bump electrodes may include gold. Since the gold is a flexible metal, the bump electrodes can be easily formed.

In manufacture of the semiconductor device, ultrasonic vibration may be applied in the step of abutting the conductive particles onto the bump electrodes and onto the first and second terminal electrodes, to form a conductive metal compound between the conductive particles and the bump electrodes, and between the conductive particles and at least one of the first and second terminal electrodes. In this step, substantially spherical bump electrodes may be depressed into the insulating resin layer, toward at least one of the first and second terminal electrodes, and are therefore deformed to have a flat surface at the distal end. In this case, the bump electrodes can be easily deformed, because the conductive particles are provided between the bump electrodes and at least one of the first and second terminal electrodes.

In manufacture of the semiconductor device, a pressure may be applied between the bump electrodes and at least one of the first and second terminal electrodes during the step of curing The conductive particles may be therefore deformed to have a flat surface due to the depression between the bump electrodes and at least one of the first and second terminal electrodes. Thereafter, the insulating resin layer may be cured.

In the method of manufacturing the semiconductor device, the insulating resin layer may be formed before attaching the same onto the electrodes or may be formed by applying a resin paste onto the electrodes.

While the invention has been particularly shown and described with reference to exemplary embodiment and modifications thereof, the invention is not limited to these embodiment and modifications. It will be understood by those of ordinary skill in the art that various changes in form and details may be made therein without departing from the spirit and scope of the present invention as defined in the claims.

What is claimed is:

1. A semiconductor device comprising:
a semiconductor chip including thereon a first terminal electrode;
a printed circuit board including thereon a second terminal electrode;
a bump electrode provided between said first electrode and said second terminal electrode for coupling together said first terminal electrode and said second terminal electrode; and
an insulating resin layer provided between said bump electrode and at least one of said first and second terminal electrodes, said insulating resin layer including therein conductive particles which are in direct contact with said bump electrode and said at least one of said first and second terminal electrodes.

2. The semiconductor device according to claim 1, wherein said conductive particles have elasticity.

3. The semiconductor device according to claim 1, wherein a conductive metal compound is formed between said conductive particles and said bump electrode and between said conductive particles and said at least one of said first and second terminal electrodes.

4. The semiconductor device according to claim 1, wherein said conductive particles disposed between said bump electrode and at least one of said first and second terminal electrodes are deformed to assume a flat shape.

5. The semiconductor device according to claim 1, wherein said bump electrode includes gold.

6. A method of manufacturing a semiconductor device including a semiconductor chip having a first terminal electrode, and a printed circuit board having a second terminal electrode, said method consecutively comprising:
forming an insulating resin layer on at least one of said first and second terminal electrodes, said insulating resin layer including therein conductive particles;
depressing a bump electrode onto at least one of said first and second terminal electrodes from above said insulating resin layer, thereby allowing said conductive particles to be in contact with said bump electrode and at least one of said first and second terminal electrodes; and
curing said insulating resin layer.

7. The method according to claim 6, wherein said depressing step includes applying ultrasonic vibration to form a conductive metal compound between said conductive particles and said bump electrode and between said conductive particles and said at least one of said first and second terminal electrodes.

8. The method according to claim 7, wherein, said depressing step depresses said bump electrode having a substantially spherical shape onto said at least one of said first and second terminal electrodes while allowing said bump electrode to penetrate said insulating resin layer, and to deform at least at a distal end thereof.

9. The method according to claim 6, wherein said curing step includes applying a pressure between said bump electrode and said at least one of said first and second terminal electrodes, to thereby deform said conductive particles between said bump electrode and said at least one of sad first and second terminal electrodes into a flat shape.

10. The method according to claim 6, wherein said bump electrode includes gold.

11. The method according to claim 6, wherein said insulating resin layer is formed as a film before said providing step.
